(19) United States
(12) Patent Application Publication
(10) Pub. No.: US 2011/0303949 A1
(43) Pub. Date: Dec. 15, 2011

(54) SEMICONDUCTOR LIGHT-RECEIVING ELEMENT

(75) Inventors: Yoshifumi Sasahata, Tokyo (JP); Masaharu Nakaji, Tokyo (JP)

(73) Assignee: MITSUBISHI ELECTRIC CORPORATION, Tokyo (JP)

(21) Appl. No.: 13/015,683

(22) Filed: Jan. 28, 2011

(30) Foreign Application Priority Data
Jun. 10, 2010 (JP) 2010-133022

(51) Int. Cl. H01L 31/0304

(52) U.S. Cl. 257/184; 257/E31.02; 257/E31.128

(57) ABSTRACT

A semiconductor light-detecting element includes: a semiconductor substrate of a first conductivity type; a light absorption recoupling layer of the first conductivity type, a multilayer reflection film of the first conductivity type, a light absorbing layer, and a window layer, which are laminated, in that order, on the semiconductor substrate; a doped region of a second conductivity type in part of the window layer; a first electrode connected to the doped region; and a second electrode connected to an underside of the semiconductor substrate. The band gap energy of the window layer is larger than the band gap energy of the light absorbing layer, and the band gap energy of the light absorption recoupling layer is smaller than the band gap energy of the semiconductor substrate.

### BACKGROUND OF THE INVENTION

1. Field of the Invention

The present invention relates to a semiconductor light-receiving element which makes it possible to lessen response distortion and suppress the decrease of light-receiving sensitivity.

2. Background Art

In recent years, with the increase in bandwidth of semiconductor light-receiving elements, the thickness of light absorption layers is reduced to 0.5 to 2 μm, resulting in a problem that sensitivity of such semiconductor light-receiving elements is decreasing. There is a report on a semiconductor light-receiving element in which a multilayer reflection film is provided below a light absorbing layer which reflects light that has passed through the light absorbing layer to suppress the decrease in light-receiving sensitivity (e.g., see FIG. 2 of Japanese Patent Laid-Open No. 9-45954).

Furthermore, when the light absorbing layer becomes thinner, the proportion of incident light that passes through the light absorbing layer without being thereby absorbed increases. The light that has passed through the light absorbing layer is reflected by an electrode on the underside of the substrate and the reflected light is absorbed in an undepleted region of the light absorbing layer and extracted as an optical current. Since the response of the optical current to the incident light is slow, there is a problem that response distortion occurs.

### SUMMARY OF THE INVENTION

When, for example, a multilayer reflection film made up of approximately ten InGaAs layers thickly laminated on each other having a large absorption coefficient with respect to incident light of wavelength 1.27 μm is used, the reflected light from the substrate is absorbed, and therefore the response distortion can be reduced. However, when the absorption coefficient is increased, the reflection factor of the multilayer reflection film is reduced, resulting in a problem that the light-receiving sensitivity of the semiconductor light-receiving element decreases.

In view of the above-described problems, an object of the present invention is to provide a semiconductor light-receiving element which makes it possible to lessen response distortion and suppress the decrease of light-receiving sensitivity.

According to the present invention, a semiconductor light-receiving element comprises: a semiconductor substrate of a first conductivity type; a light absorption recoupling layer of the first conductivity type, a multilayer reflection film of the first conductivity type, a light absorbing layer and a window layer which are laminated in that order on the semiconductor substrate; a doped region of a second conductivity type in part of the window layer; a first electrode connected to the doped region; and a second electrode connected to an underside of the semiconductor substrate, wherein band gap energy of the window layer is greater than band gap energy of the light absorbing layer, and band gap energy of the light absorption recoupling layer is smaller than band gap energy of the semiconductor substrate.

The present invention makes it possible to lessen response distortion and suppress the decrease of light-receiving sensitivity.

Other and further objects, features and advantages of the invention will appear more fully from the following description.

### BRIEF DESCRIPTION OF THE DRAWINGS

FIG. 1 is a cross-sectional view illustrating a semiconductor light-receiving element according to First embodiment.

FIG. 2 is a cross-sectional view illustrating a semiconductor light-receiving element according to a comparative example.

FIG. 3 is a cross-sectional view illustrating a semiconductor light-receiving element according to Second embodiment.

FIG. 4 is a cross-sectional view illustrating a semiconductor light-receiving element according to Third embodiment.

FIG. 5 is a cross-sectional view illustrating a semiconductor light-receiving element according to Fourth embodiment.

### DETAILED DESCRIPTION OF THE PREFERRED EMBODIMENTS

A semiconductor light-receiving element according to the embodiments of the present invention will be described with reference to the drawings. The same components will be denoted by the same symbols, and the repeated description thereof may be omitted.

### First Embodiment

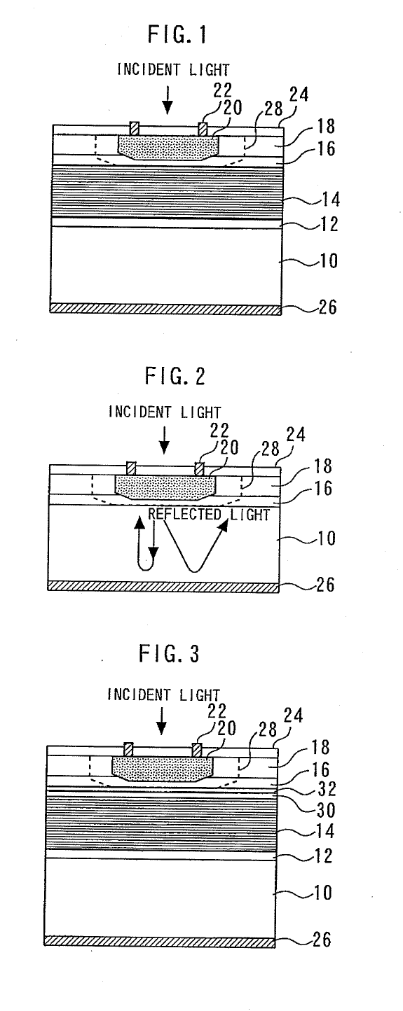

FIG. 1 is a cross-sectional view illustrating a semiconductor light-receiving element according to First embodiment. This semiconductor light-receiving element is an InGaAs-based photodiode.

A light absorption recoupling layer 12 made of n-type InGaAs having carrier concentration of 1×10¹⁹ cm⁻³ and having a thickness of approximately 0.5 to 2.0 μm, an n-type multilayer reflection film 14 having carrier concentration of approximately 5×10¹⁸ cm⁻³, a light absorbing layer 16 made of undoped InGaAs having a thickness of approximately 0.5 to 2 μm and a window layer 18 made of undoped InP having a thickness of approximately 2 μm are laminated in that order on an n-type InP substrate 10 having carrier concentration of 5×10¹⁸ cm⁻³.

A p-type doped region 20 having carrier concentration of 1×10¹⁹ to 1×10²⁰ cm⁻³ is formed in part of the window layer 18. A p-side electrode 22 made of Ti/Au or the like is connected to the p-type doped region 20. A surface protective film 24 made of SiN is formed on the window layer 18. An n-side electrode 26 made of AuGe/Au is connected to the underside of the n-type InP substrate 10.

Here, the wavelength of incident light is 1.26 μm to 1.36 μm, and, for example, 1.27 μm which is an optical communication wavelength band. The band gap energy of the window layer 18 is greater than the band gap energy of the light absorbing layer 16. The band gap energy of the light absorption recoupling layer 12 is smaller than the band gap energy of the n-type InP substrate 10. The multilayer reflection film 14 is a Bragg reflection film made up of InP layers and InAlGaAs layers of different refractive indexes having a thickness ¼ of the wavelength of the incident light alternately laminated on each other. The thickness of the surface protective film 24 is ¼ of the wavelength of the incident light. The surface protective film 24 also functions as an anti-reflection film.

Next, a method of manufacturing the above described semiconductor light-receiving element will be described briefly. First, the light absorption recoupling layer 12, multilayer reflection film 14, light absorbing layer 16 and window layer 18 are sequentially made to epitaxially grow on the n-type InP substrate 10 using an MOCVD (Metal organic chemical vapor deposition) or the like.

Next, Zn is made to diffuse in part of the window layer 18 from the surface thereof until Zn reaches the light absorbing layer 16 to form the p-type doped region 20. This diffusion method is vapor phase diffusion, thermal diffusion or the like using a mask or the like. For example, when thermal diffusion is performed, a film of a diffusion source such as a SiN film (not shown) or the like is formed, an opening is formed in the region in which the p-type doped region 20 of the SiN film is formed, a ZnO film (not shown) or the like is formed on the SiN film including the region in the opening, and thermal processing is performed using the SiN film as a mask for a predetermined time. An impurity such as Cd or Be may be used for diffusion instead of Zn. After that, the SiN film and ZnO film or the like are removed.

Next, the surface protective film 24 is formed on the surface of the window layer 18 using a plasma CVD method or the like. An opening is formed in the region of the surface protective film 24 in which the p-side electrode 22 is to be formed later by combining a photolithography technique and etching using fluorinated acid or the like. A photoresist film (not shown) is formed on the surface protective film 24, the photoresist film is patterned, another opening is formed in the region of the opening of the surface protective film 24, a Ti/Au film is formed through electron beam (EB) vapor deposition, an unnecessary portion of the film is lifted off together with the photoresist film and the p-side electrode 22 is formed. In this case, a bonding pad (not shown) connected to the p-side electrode 22 is simultaneously formed on the surface protective film 24. After that, the underside of the n-type InP substrate 10 is polished and the n-side electrode 26 is formed on the underside of the n-type InP substrate 10. The semiconductor light-receiving element shown in FIG. 1 is manufactured through the above described steps.

Next, the basic operation of the semiconductor light-receiving element will be described. A reverse bias voltage is applied from outside so that the n-side electrode 26 becomes plus and the p-side electrode 22 becomes minus. In such a condition, a depletion layer 28 is formed in the light absorbing layer 16 with a pn junction made up of the p-type doped region 20 and the n-type InP substrate 10. Incident light made incident on the p-type doped region 20 from above the semiconductor light-receiving element passes through the surface protective film 24 and the InP window layer 18, is absorbed by the depletion layer 28 of the light absorbing layer 16, where electrons and holes are generated. The electrons and holes are attracted by the electric field and flow toward the n-type InP substrate 10 and the p-type doped region 20 respectively. An optical current generated in this way is extracted from the p-side electrode 22 and the n-side electrode 26 as a signal current.

Next, effects of First embodiment will be described in comparison with a comparative example. FIG. 2 is a cross-sectional view illustrating a semiconductor light-receiving element according to a comparative example. The comparative example includes neither the light absorption recoupling layer 12 nor the multilayer reflection film 14 of First embodiment.

In the comparative example, when the light absorbing layer 16 becomes thinner, sensitivity of the semiconductor light-receiving element decreases. On the other hand, in the present embodiment, much of the incident light that has passed through the light absorbing layer 16 without being absorbed is reflected by the multilayer reflection film 14 and absorbed by the light absorbing layer 16. Therefore, the decrease of light-receiving sensitivity can be suppressed.

Furthermore, in the comparative example, the incident light that has passed through the light absorbing layer 16 without being absorbed is reflected by the n-side electrode 26, the reflected light thereof is absorbed in the undepleted region of the light absorbing layer 16 and extracted as an optical current. Since the response of the optical current to the incident light is slow, response distortion occurs. On the other hand, in the present embodiment, the light that has passed through the light absorbing layer 16 without being absorbed and that has passed through the multilayer reflection film 14 without being reflected is absorbed by the light absorption recoupling layer 12, and electrons and holes are generated. Since the light absorption recoupling layer 12 is doped with impurities, the electrons and holes generated in the light absorption recoupling layer 12 are not left'indwelling but are recoupled and disappear. Therefore, response distortion can be lessened.

Here, the optical thickness of the light absorption recoupling layer 12 is preferably an integer multiple of ¼ of the wavelength of the incident light. This causes the light absorption recoupling layer 12 to also exercise the function of a multilayer reflection film, and can thereby suppress the decrease of the reflection factor. Furthermore, the thickness of the light absorption recoupling layer 12 is preferably 0.5 μm or more. In this way, substantially all the light that has passed through the light absorbing layer 16 and the multilayer reflection film 14 can be absorbed.

Furthermore, when the multilayer reflection film 14 is made of a material having large absorption with respect to the incident light wavelength, the reflection factor of the multilayer reflection film 14 decreases. Thus, to reduce absorption of the incident light in the multilayer reflection film 14, the band gap energy of the multilayer reflection film 14 is preferably greater than 0.8 eV. This makes it possible to increase the reflection factor of the multilayer reflection film 14. As a result, the proportion of incident light that passes through the multilayer reflection film 14 decreases and response distortion can thereby be reduced.

For example, in a light-receiving element for incident light having a wavelength of 1.27 μm, when a multilayer reflection film made up of InP layers and InGaAs layers (band gap energy 0.75 eV) alternately laminated on each other is used, since light absorption in the InGaAs layer is large, a high reflection factor cannot be obtained. On the other hand, when the multilayer reflection film made up of InP layers and InAlGaAs layers alternately laminated on each other is used, since light absorption in the InAlGaAs layer is small, a high reflection factor can be obtained. However, as the Al composition increases, the refractive index difference decreases, and therefore the reflection factor reaches a maximum with a certain Al composition, and then gradually decreases. Therefore, the Al composition of the multilayer reflection film 14 is selected so that the reflection factor reaches a maximum. Furthermore, even in the case of a multilayer reflection film made up of InP layers and InGaAsP layers alternately laminated on each other, there is an optimum P composition likewise.

Although the present embodiment assumes the light absorption recoupling layer 12 to be n-type InGaAs, the light absorption recoupling layer 12 may be n-type InGaAsP or n-type AlGaInAs.

### Second Embodiment

FIG. 3 is a cross-sectional view illustrating a semiconductor light-receiving element according to Second embodiment. This semiconductor light-receiving element is an avalanche photodiode which corresponds to the configuration of First embodiment with an addition of an avalanche multiplication layer 30 that multiplies a carrier generated by the light absorbing layer 16 and an electric field relaxation layer 32 that relaxes electric field strength from the avalanche multiplication layer 30 to the light absorbing layer 16.

The avalanche multiplication layer 30 is provided between the multilayer reflection film 14 and the light absorbing layer 16 and the electric field relaxation layer 32 is provided between the avalanche multiplication layer 30 and the light absorbing layer 16. The electric field relaxation layer 32 has a thickness of 0.03 to 0.06 μm and is made of p-type InP having carrier concentration of 0.5 to 1×10¹⁸ cm⁻³. The avalanche multiplication layer is made of undoped AlInAs having a thickness of 0.15 to 0.4 μm.

When the reverse bias voltage applied to the semiconductor light-receiving element is sufficiently high, electrons are ionized in the avalanche multiplication layer 30 and new pairs of electrons and holes are generated. The newly generated electrons and holes cause further ionization and electrons and holes are multiplied like an avalanche (avalanche multiplication). This allows light-receiving sensitivity to increase.

Although the present embodiment assumes the electric field relaxation layer 32 to be p-type InP, the electric field relaxation layer 32 may be p-type AlInAs. The electric field relaxation layer 32 may be omitted depending on the situation.

### Third Embodiment

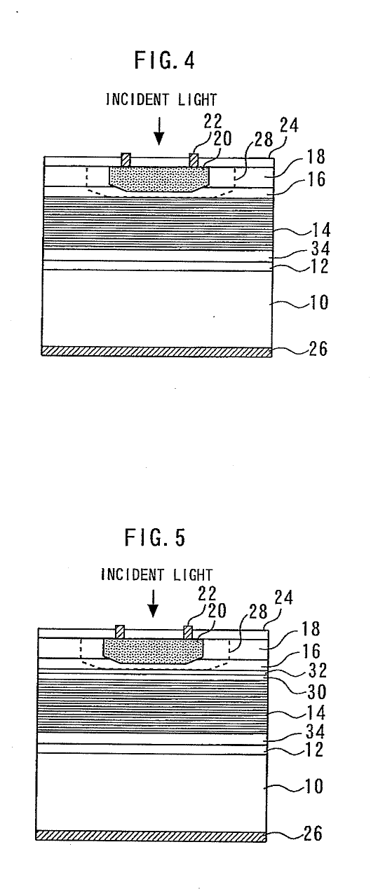

FIG. 4 is a cross-sectional view illustrating a semiconductor light-receiving element according to Third embodiment. This semiconductor light-receiving element is a photodiode that corresponds to the configuration of First embodiment with an addition of a barrier layer 34.

The barrier layer 34 is provided between the light absorption recoupling layer 12 and the light absorbing layer 16 and made of n-type AlInAs or n-type AlGaInAs having carrier concentration of 1×10¹⁸ cm⁻³ and a thickness of approximately 0.5 μm. The band gap energy of the barrier layer 34 is sufficiently greater than the band gap energy (0.75 eV) of the light absorption recoupling layer 12.

Here, incident light that has passed through the multilayer reflection film 14 is absorbed by the light absorption recoupling layer 12 and electrons and holes are generated. If the electrons and holes drift by diffusion and reach the depletion layer 28 by the time the electrons and holes disappear, the electrons and holes are extracted as an optical current and become a signal distortion component. By contrast, in the present embodiment, the barrier layer 34 prevents electrons and holes from flowing into the depletion layer 28, and can thereby reduce response distortion.

### Fourth Embodiment

FIG. 5 is a cross-sectional view illustrating a semiconductor light-receiving element according to Fourth embodiment. This semiconductor light-receiving element is an avalanche photodiode corresponding to the configuration of First embodiment with an addition of the electric field relaxation layer 32 and the avalanche multiplication layer 30 of Second embodiment and the barrier layer 34 of Third embodiment. Fourth embodiment can thereby obtain the effects of First to Third embodiments.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2010-133022, filed on Jun. 10, 2010 including specification, claims, drawings and summary, on which the Convention priority of the present application is based, are incorporated herein by reference in its entirety.

1. A semiconductor light-detecting element comprising:
a semiconductor substrate of a first conductivity type;
a light absorption recoupling layer of the first conductivity type, a multilayer reflection film of the first conductivity type, a light absorbing layer, and a window layer which are laminated, in that order, on the semiconductor substrate;
a doped region of a second conductivity type in part of the window layer;
a first electrode connected to the doped region; and
a second electrode connected to an underside of the semiconductor substrate, wherein
band gap energy of the window layer is larger than band gap energy of the light absorbing layer, and
band gap energy of the light absorption recoupling layer is smaller than band gap energy of the semiconductor substrate.

2. The semiconductor light-detecting element according to claim 1, wherein the multilayer reflection film is a Bragg reflection film including two semiconductor layers of different refractive indexes, having a thickness ¼ of one wavelength of incident light that is detected, and alternately laminated on each other.

3. The semiconductor light-detecting element according to claim 1, wherein optical thickness of the light absorption recoupling layer is an integer multiple of ¼ of one wavelength of incident light that is detected.

4. The semiconductor light-detecting element according to claim 1, wherein band gap energy of the multilayer reflection film is larger than 0.8 eV.

5. The semiconductor light-detecting element according to claim 1, wherein the semiconductor substrate is InP, and the light absorption recoupling layer selected from the group consisting of InGaAs, InGaAsP, and AlGaInAs.

6. The semiconductor light-detecting element according to claim 1, further comprising a multiplication layer which is located between the multilayer reflection film and the light absorbing layer and which multiplies charge carriers generated by the light absorbing layer.

7. The semiconductor light-detecting element according to claim 1, further comprising a barrier layer which is located between the light absorption recoupling layer and the light absorbing layer, wherein band gap energy of the barrier layer is larger than band gap energy of the light absorption recoupling layer.

8. The semiconductor light-detecting element according to claim 7, wherein the barrier layer is one of AlInAs and AlGaInAs.
